(19) United States
(12) Patent Application Publication
(10) Pub. No.: US 2026/0068241 A1
(43) Pub. Date: Mar. 5, 2026

(54) EPI LINER SUPER JUNCTION DEVICES WITH DIFFUSION BARRIER

(71) Applicant: Applied Materials, Inc., Santa Clara, CA (US)

(72) Inventors: Amirhasan NOURBAKHSH, Albany, NY (US); Raman GAIRE, Mechanicville, NY (US)

(73) Assignee: Applied Materials, Inc., Santa Clara, CA (US)

(21) Appl. No.: 18/820,004

(22) Filed: Aug. 29, 2024

(51) Int. Cl. H01L 29/06; H01L 21/02; H01L 21/3065

(52) U.S. Cl. CPC H10D 62/111

(57) ABSTRACT

A super junction device with an increased voltage rating may be formed by creating a P liner on the sidewalls of a trench etched into N material, then filling the trench with additional N-type material. This thin P liner may be doped at a significantly higher concentration than the surrounding N material to maintain a charge balance. However, these relatively thin dimensions and the high doping concentration differential may cause P dopants to diffuse into the N material during subsequent high-temperature manufacturing processes. Diffusion barriers on either side of the P liner prevent diffusion of the dopants into the surrounding N material. The diffusion barriers create an abrupt interface between the N and P materials that prevents diffusion and improves the performance of the super junction devices.

### TECHNICAL FIELD

The present technology relates to semiconductor manufacturing systems, processes, and equipment. More specifically, the present technology relates to super junction devices and methods for asymmetric P-type and N-type regions separated by diffusion barriers.

### BACKGROUND

Integrated circuits are made possible by processes which produce intricately patterned material layers on substrate surfaces. Super junction semiconductor devices in particular are designed to efficiently handle high voltages and currents, making them ideal for a wide range of applications, from power supplies and inverters, to electric vehicles and renewable energy systems. Unlike traditional semiconductor devices, super junction devices utilize a unique structure that incorporates alternating layers of differently doped semiconductor materials. This design significantly reduces on-state resistance and enhances switching performance, leading to improved energy efficiency and higher power density. The alternating layers include multiple vertical pillars that create a series of channels through which current flows, enabling efficient charge balancing and minimizing the electric field concentration. However, these vertical channels create high aspect ratios that are difficult to etch and fill uniformly. Thus, there is a need for improved systems and methods that can be used to produce high quality super junction devices and structures.

### SUMMARY

In some embodiments, an asymmetric super junction device may include an N-type region extending between a gate and a substrate of the asymmetric super junction device; a P-type region extending between a source contact region and the substrate of the asymmetric super junction device; and a diffusion barrier between the P-type region and the N-type region.

In some embodiments, a super junction device may include a first N-type pillar; a second N-type pillar; a P-type liner between the first N-type pillar and the second N-type pillar; and diffusion barriers between the P-type liner and the first N-type pillar and between the P-type liner and the second N-type pillar.

In some embodiments, a method of forming a super junction device may include forming an first N-type material over a substrate; etching a trench in the first N-type material; forming a diffusion barrier on a sidewall portion of the first N-type material in the trench; forming a P-type liner on the diffusion barrier; and filling the trench with a silicon material.

In any embodiments, any and all of the following features may be implemented in any combination and without limitation. A width of the P-type region may be less than or about 10% of a combined width of the P-type region and the N-type region. A second diffusion barrier may be between the P-type region and a second N-type region, and the P-type region may be between the N-type region and the second N-type region. The diffusion barrier may reduce diffusion of P-type dopants in the P-type region into the N-type region. A doping concentration of the N-type region may be between about 1e14 dopants/cm3 and about 1e16 dopants/cm3. A doping concentration of the P-type region may be greater than about 8 times a doping concentration of the N-type region. A height of the P-type region may be greater than or about 70 μm and a width of the P-type region is less than or about 200 nm. A height of the first N-type pillar may be greater than about 80 μm, and the super junction device may have a breakdown voltage of greater than or about 1200 V. A doping concentration of the P-type liner may be higher than a doping concentration of the first N-type pillar. The diffusion barriers may include doped silicon. The diffusion barriers may include doped silicon germanium. The diffusion barriers may be between about 1 nm and 10 nm thick. A second diffusion barrier may be formed on the P-type liner. An oxide layer may be formed over the P-type liner and on a bottom of the trench. A directional etch may be performed to remove the P-type liner from the bottom of the trench while leaving the P-type liner along the sidewall portion of the trench. The P-type liner may be less than or about 300 nm thick. A doping concentration of the N-type material may be between about 1e14 dopants/cm3 and about 1e16 dopants/cm3. The diffusion barrier and the P-type liner may be epitaxially formed.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of a processing system of deposition, etching, baking, and curing chambers that may be included or configured according to some embodiments of the present technology.

FIG. 2 illustrates a traditional super junction device, according to some embodiments.

FIG. 3 illustrates an example of a super junction device a higher breakdown voltage, according to some embodiments.

FIG. 4 illustrates a flowchart of a method of forming an asymmetric super junction device with diffusion barriers, according to some embodiments.

FIGS. 5A-5G illustrate incremental structures for forming the asymmetric super junction device with diffusion barriers, according to some embodiments.

FIG. 6 illustrates a graph of the concentration of dopants in the P-type liner, according to some embodiments.

### DETAILED DESCRIPTION

Creating a P-type liner on the sidewalls of a trench etched into N-type material, then filling the trench with additional N-type material is a new technique for creating high-voltage super junction devices with aspect ratios that cannot be reliably filled with conventional processes. This thin P-type liner may be doped at a significantly higher concentration in the surrounding N-type material to maintain a charge balance. However, these relatively thin dimensions and the high doping concentration differential may cause P-type dopants to diffuse into the N-type material during subsequent high-temperature manufacturing processes. This technology uses diffusion barriers on either side of the P-type liner to prevent diffusion of the dopants into the surrounding N-type material. These diffusion barriers may be epitaxially grown to surround the P-type liner on the sidewalls of the trench. The diffusion barriers create an abrupt interface between the N-type and P-type materials that prevents diffusion and improves the performance of the super junction devices.

As device sizes continue to shrink, many material layers may be reduced in thickness and size to scale devices. Features inside semiconductor structures may be reduced in size, and aspect ratios of the features may increase. As the aspect ratios of the features increase, patterning operations may struggle to uniformly etch features without tapering the sidewalls of the feature, or compromising feature dimensions or integrity, due to increased exposure nearer a surface of the substrate material being processed. Further, refilling a feature with higher aspect ratios may be increasingly difficult due to pinch off at the top of the feature that prevents the feature from being filled without seams and/or voids.

In forming power device structures, conventional technologies have been limited in device scaling for increased aspect ratio features based on the natural effects of prolonged etching and deposition operations. For example, in super junction structures, p-type silicon pillars are formed by filling trenches etched into n-type silicon with p-type material. In these structures, the on-resistance is controlled by the pitch or width of the different materials. The resistance may be improved by reducing the width of the p-type silicon pillars. Scaling the p-type silicon pillars is limited by etching and seam and/or void free trench filling capabilities. For example, increasing the aspect ratio with conventional etching may cause pitch degradation and tapered features due to the prolonged exposure of upper regions of the feature being formed. Additionally, the fill operation of high-aspect ratio features may lead to pinch off before deeper regions of the feature are filled. Consequently, conventional technologies have been limited to lower aspect ratios, or shorter structures to limit performance effects or device failure. Accordingly, many conventional technologies have been limited in the ability to prevent structural flaws in the final devices or improve on historical designs.

In order to accommodate higher aspect ratio features, a new technique forms a thin epitaxial liner within a wider overall feature prior to backfill, the pillars of material can be maintained at much smaller widths compared to conventional technologies. More specifically, the width of the pillars of material may be defined by the width of the epitaxial liner rather than the width of the recessed features. In fact, the recessed features can be made wider than conventional technologies as two pillars may be deposited on both sidewalls of each recessed feature or trench. After forming materials on the sidewalls, the recessed features may be backfilled with additional silicon material. By changing the formation process itself, the present technology may afford much greater aspect ratio features, and also may prevent or reduce defects in final devices based on more uniform fill and coverage.

This new technique creates very asymmetric super junction devices, where the P-type liner formed along the sidewalls of N-type mesas or pillars is significantly thinner in comparison to the thickness of the N-type pillars. In some devices, this may create a technical problem where the relatively large difference in doping concentrations between the P-type liner and the N-type pillars causes diffusion drift of the P-type dopant into the N-type pillars. The embodiments described herein solve these and other technical problems by forming a diffusion barrier around the P-type liner in the device. These diffusion barriers effectively prevent the diffusion of P-type dopants into the N-type regions in the asymmetric super junction device, and create an abrupt transition between these two regions even during relatively high temperatures that may be experienced during remaining manufacturing processes.

Although the remaining disclosure will routinely identify specific etching, deposition, and other manufacturing processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

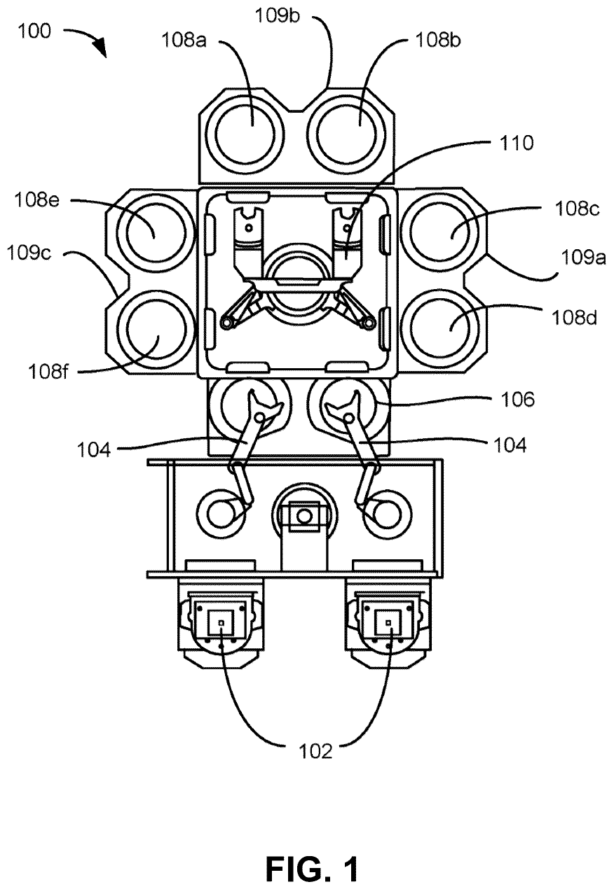

FIG. 1 shows a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108c-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

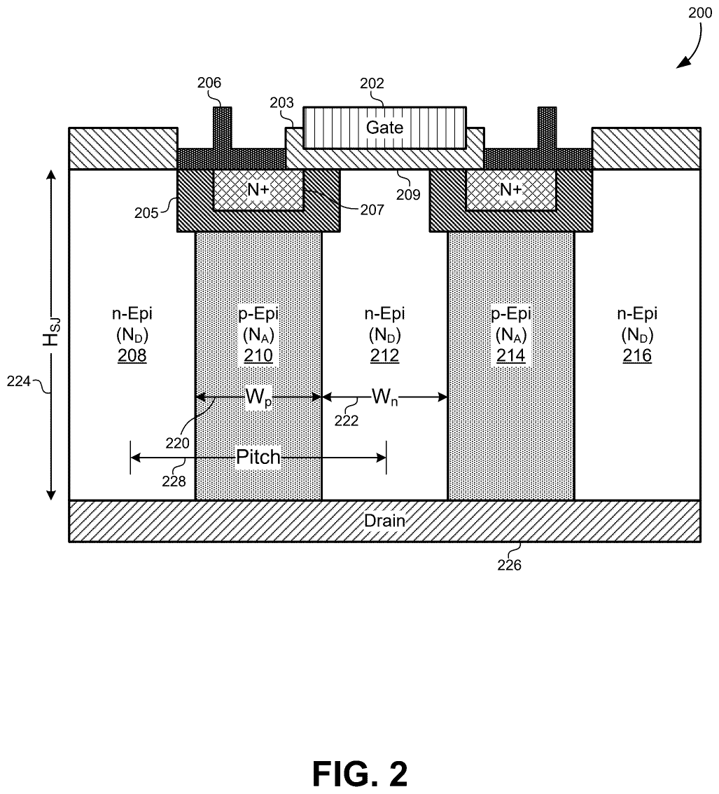

System 100, or more specifically chambers incorporated into system 100 or other processing systems, may be used to produce structures according to some embodiments of the present technology. FIG. 2 illustrates a traditional super junction device 200, according to some embodiments. The device 200 in FIG. 2 is represented by example as a super junction transistor, such as a super junction MOSFET. However, the principles described herein may be used to form any super junction device, and the description is not limited to a super junction transistor.

The device 200 may include a number of different electrical contacts. The device 200 may include a source contact 206 that is electrically coupled to an N+ source region 207 that is formed within a P-well 205. Collectively, the source contact 206, the N+ source region 207, and the P-well 205 may be referred to as a “source region” of the device 200. The device may be formed on a silicon substrate 226. The silicon substrate 226 may form a drain region of the device 200. Although not shown explicitly in FIG. 2, the drain region formed by the substrate 226 may include a conductive contact similar to the source contact 206. The device 200 may also include a gate region that includes a gate contact 202 and a gate oxide 209. Each of the source, drain, and gate regions may include other layers or regions that are not explicitly shown in FIG. 2. Additionally, these contacts may also be referred to in this disclosure more generically as a “first,” “second,” and “third” contact to distinguish one contact from the other in a manner that is not specific to a transistor. For example, in this transistor implementation, the drain region may be referred to as a first contact region, the gate region may be referred to as a second contact region, and the source region may be referred to as a third contact region.

The internal regions of the device 200 may include a plurality of N-doped regions and/or P-doped regions. These regions may also be referred to as “pillars,” as these regions typically extend from the silicon substrate 226 up to the top of the device 200. The device 200 may include a first N-type region 208 that extends orthogonally up from the silicon substrate 226 to the top of the device 200. The device 200 may also include a P-type region 210 that also extends orthogonally up from the silicon substrate 226 to the source region of the device 200. The device 200 may also include a second N-type region 212 that similarly extends orthogonally up from the silicon substrate 226 to the gate region. Note that the device 200 may also include additional contact regions, P-type regions (e.g., P-type region 214), and N-type regions (e.g., N-type region 216), some of which are illustrated in FIG. 2.

Typically, the width 220 of the P-type region 210 and the width 222 of the second N-type region 212 are approximately the same in standard super junction devices. Additionally, a doping level (NA) of the P-type region 210 and a doping level (ND) of the N-type region 212 are also equal. In order to function optimally, the charge should be balance between the second N-type region 212 and the P-type region 210 according to the following equation.

$${N}_{A} {W}_{p} = {N}_{D} {W}_{n} \qquad ( 1 )$$

With careful charge balancing between the N-type pillars in the P-type pillars in the device 200, these regions may completely deplete each other to form a depletion region throughout the bulk of the device 200. Full depletion increases the breakdown voltage of the device 200 significantly without lowering the doping concentrations. This allows the device to have very high doping concentrations in the N-type regions so long as the balance is maintained according to equation (1) above.

The breakdown voltage of the device 200 is also a function of the height 224 of the device 200. Typically, the greater the height 224 of the device 200, the higher the breakdown voltage of the device 200. However, manufacturing limitations have limited the height 224 of the device 200 due to aspect ratios of the features. Specifically, forming the device typically includes forming an N-type material on top of the silicon substrate 226. Trenches are then etched in the N-type region, leaving N-type mesas that include, for example, N-type region 208, N-type region 212, and so forth. The trenches are then filled with the P-type material to form the P-type regions, such as P-type region 210, P-type region 214, and so forth. Therefore, the aspect ratio of the trench limits the depth of the trench unless the width of the trench is increased. However, increasing the width of the trench increases the total size of the device 200. With shrinking device sizes, increasing the size of the device to increase the breakdown voltage is not a feasible option in most applications.

For example, the device 200 in FIG. 2 may be rated as a 650 V device. The specifications for this 650 V device include a height 224 of about 40 μm. The width 220 of the P-type region 210 is about 2 μm (also referred to as a critical dimension or “CD”). This leads to an aspect ratio of 40/2=20 for a trench that is etched to form the P-type region 210. The pitch 228 is about 4 μm, which may be defined as the distance between centers of consecutive N-type regions. The aspect ratio of 20 has been found to be an acceptable feature size for current etch and fill operations for devices of this size. Increasing the aspect ratio beyond 20 at this size can cause problems when etching the trenches. Specifically, the trenches may erode at the top surface of the trench, and may develop sloped sidewalls with a poorly defined bottom in the trench. Increasing the aspect ratio may also cause problems when filling the trenches. When depositing material in the trenches, the material may close off the trench at the top before the trench is filled throughout the height of the trench. This may cause voids or seams in the P-type regions that interfere with the operation of the device 200.

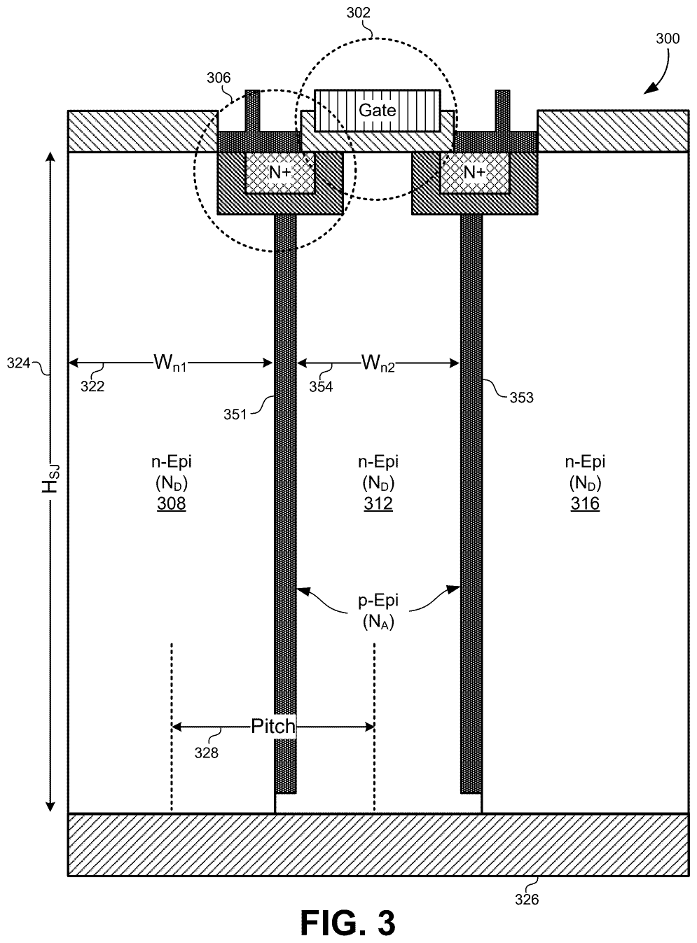

FIG. 3 illustrates an example of a super junction device 300 a higher breakdown voltage, according to some embodiments. In order to accommodate such high aspect ratios, traditional trenches in the N-type material cannot be simply filled with P-type material. For example, traditional techniques used alternating deposition and etch cycles to fill these deep trenches with P-type material. However, these techniques were unable to avoid seams, voids, an early pinch off entirely. To overcome this problem, a trench may be etched in the N-type material, and instead of filling with P-type material entirely, the trench may be lined with an epitaxial P-type liner. The liner may perform thin columns of P-type material that is doped at a much higher concentration than the surrounding N-type material to maintain a charge balance. This new technique forms a thin P-type liner within a wider overall feature prior to backfill such that the pillars of P-type material can be maintained at much smaller widths compared to conventional technologies. More specifically, the width of the pillars of material may be defined by the width of the epitaxial liner rather than the width of the recessed features. The recessed features can then be made wider than conventional technologies as two pillars may be deposited on both sidewalls of each recessed feature or trench. After forming materials on the sidewalls, the recessed features may be backfilled with additional silicon material. By changing the formation process itself, the present technology may afford much greater aspect ratio features, and also may prevent or reduce defects in final devices based on more uniform fill and coverage.

This new technique creates very asymmetric super junction devices, where the P-type liner formed along the sidewalls of N-type mesas or pillars is significantly thinner in comparison to the thickness of the N-type pillars. As described below, the P-type liner may represent less than or about 10% of the total pitch of the device. In order to maintain a charge balance, the P-type liner may be doped with a much higher concentration than the N-type pillars surrounding the P-type liner. In some devices, this may create a technical problem where the relatively large difference in doping concentrations between the P-type liner and the N-type pillars causes diffusion drift of the P-type dopant into the N-type pillars. For example, a boron-doped P-type liner may diffuse boron into the N-type pillars as a result of the high temperatures experienced typical manufacturing processes. This may result in a less abrupt transition between the N-type and P-type regions in the device. The resulting gradual transition between these two regions may degrade the performance of the device significantly.

For example, the asymmetric device of 300 of FIG. 3 may include a gate region 302 and/or a source contact region 306 to complement a drain contact region formed by the substrate 326. The P-type region 351 may be disposed between a first N-type region 308 and the second N-type region 312 with a much thinner width. To maintain the proper charge balance, the doping level of the P-type region 351 may be increased accordingly. The doping level of the first N-type region 308 and/or the second N-type region 312 may be between about 1e14 dopants/cm3 and about 1e16 dopants/cm3. In contrast, the doping level of the P-type region 351 may be greater than or about 8 times, greater than or about 9 times, greater than or about 10 times, and so forth, of the doping level of the first N-type region 508 two maintain a charge balance. This asymmetric super junction device 300 provides roughly double the breakdown voltage of the device in FIG. 2. In order to double the voltage, the height 324 of the device 300 has been doubled without doubling the aspect ratio for the trench/fill operations. This type of super junction device may be referred to herein as an “asymmetric” super junction device where there is a relatively large differential between the width of the P-type regions and the N-type regions.

However, this new technique creates very asymmetric super junction devices, where the P-type liner formed along the sidewalls of N-type mesas or pillars is significantly thinner in comparison to the thickness of the N-type pillars. As described below, the P-type liner may represent less than or about 10% of the total pitch of the device. In order to maintain a charge balance, the P-type liner may be doped with a much higher concentration than the N-type pillars surrounding the P-type liner. In some devices, this may create a technical problem where the relatively large difference in doping concentrations between the P-type liner and the N-type pillars causes diffusion drift of the P-type dopant into the N-type pillars. For example, a boron-doped P-type liner may diffuse boron into the N-type pillars as a result of the high temperatures experienced typical manufacturing processes. This may result in a less abrupt transition between the N-type and P-type regions in the device. The resulting gradual transition between these two regions may degrade the performance of the device significantly.

The embodiments described herein solve these and other technical problems by forming a diffusion barrier around the P-type liner in the device. For example, doped silicon or doped silicon germanium may form relatively thin diffusion barriers on one or both sides of the P-type liner. These diffusion barriers effectively prevent the diffusion of P-type dopants into the N-type regions in the asymmetric super junction device, and create an abrupt transition between these two regions even during relatively high temperatures (e.g., greater than about 500° C.) that may be experienced during remaining manufacturing processes.

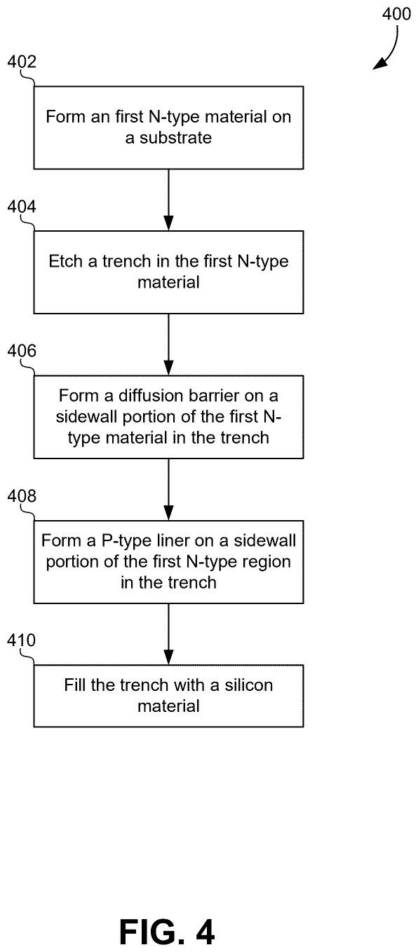

FIG. 4 illustrates a flowchart 400 of a method of forming an asymmetric super junction device with diffusion barriers, according to some embodiments. The method of flowchart 400 may be performed in one or more processing chambers, such as chambers incorporated in the system 100 described above. The method of flowchart 400 may or may not include one or more operations prior to the initiation of the method, including front-end processing, deposition, etching, polishing, cleaning, or any other operations that may be performed prior to the described operations. The method may also include a number of optional operations as denoted in the figure, which may or may not be specifically associated with some embodiments of methods according to the present technology.

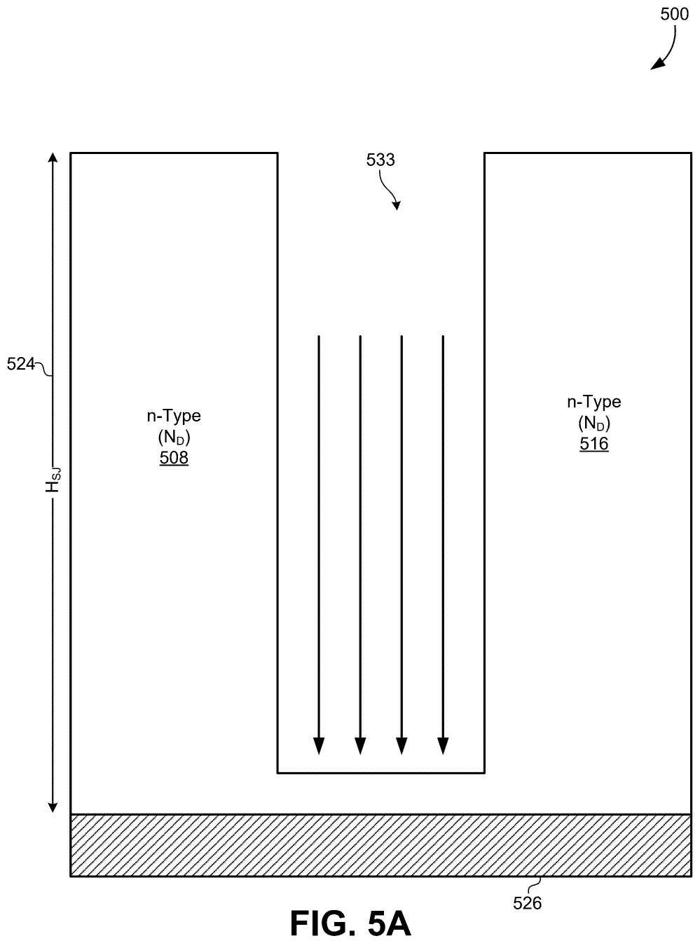

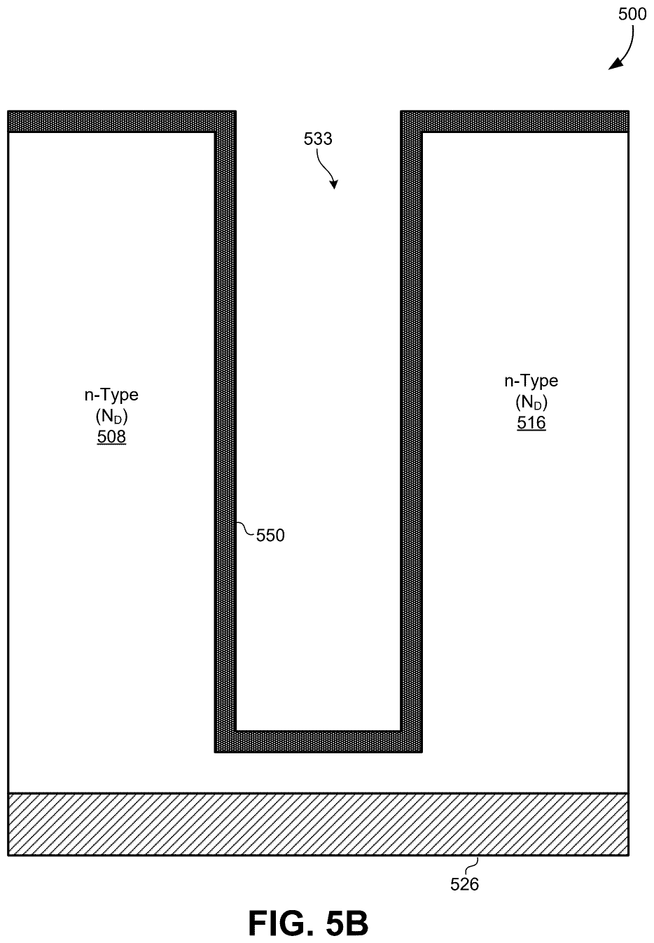

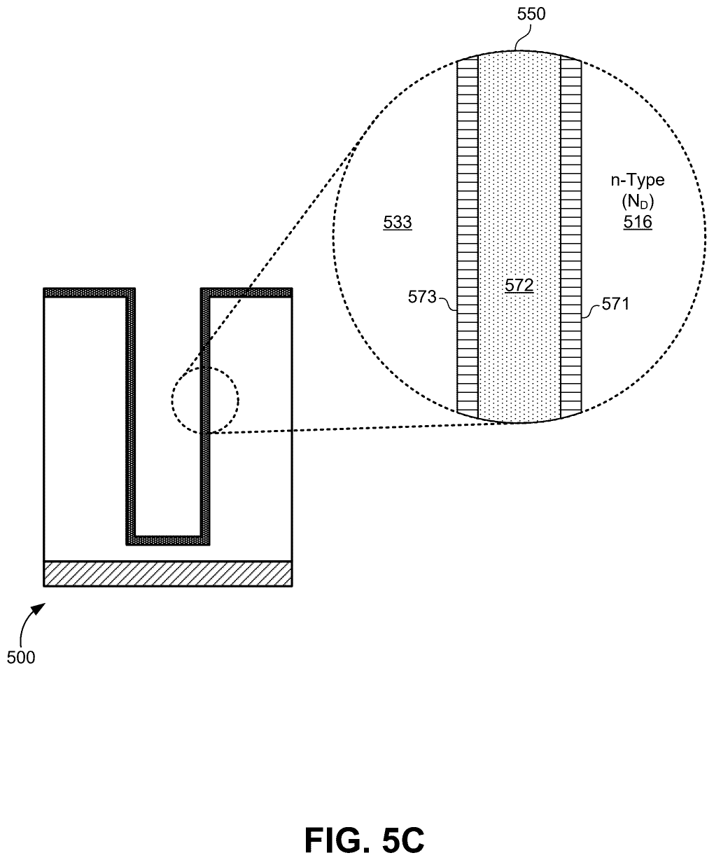

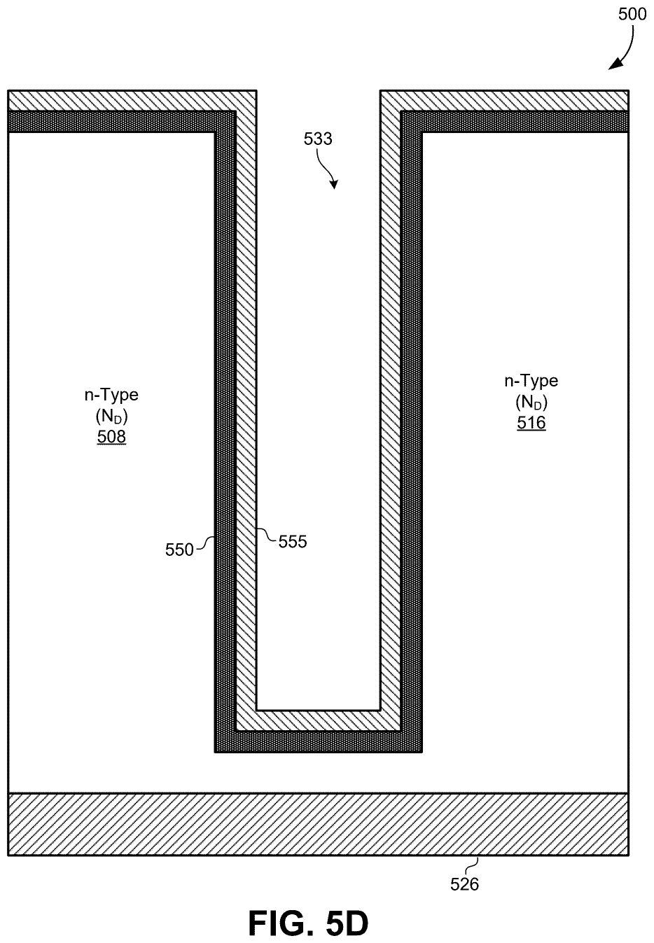

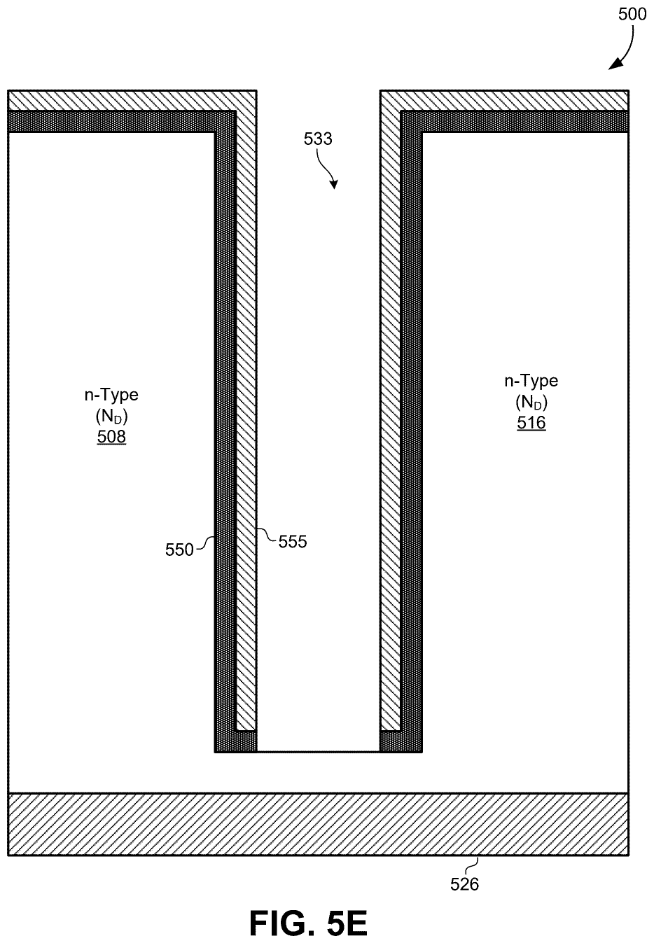

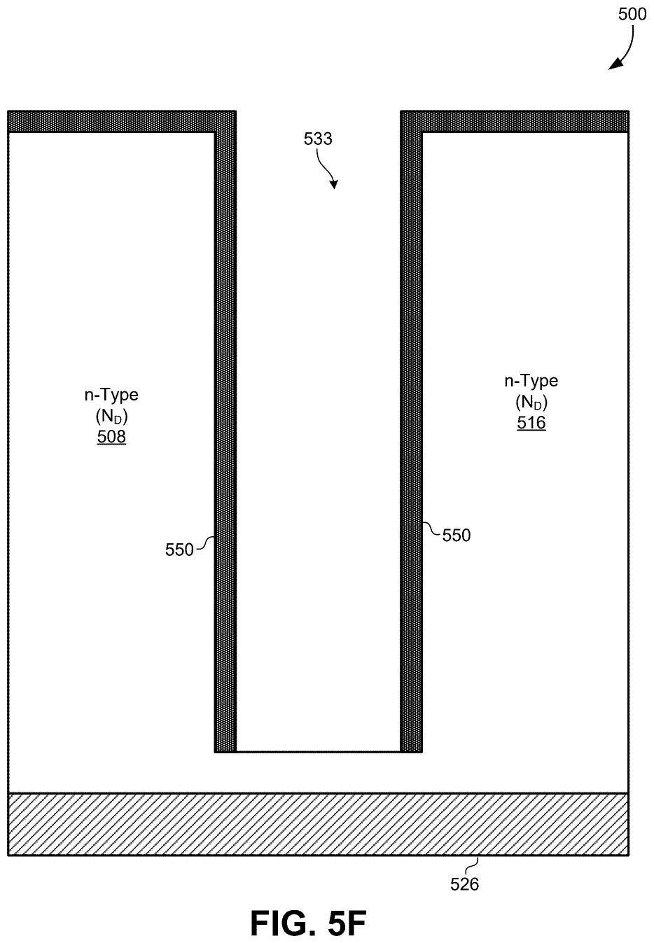

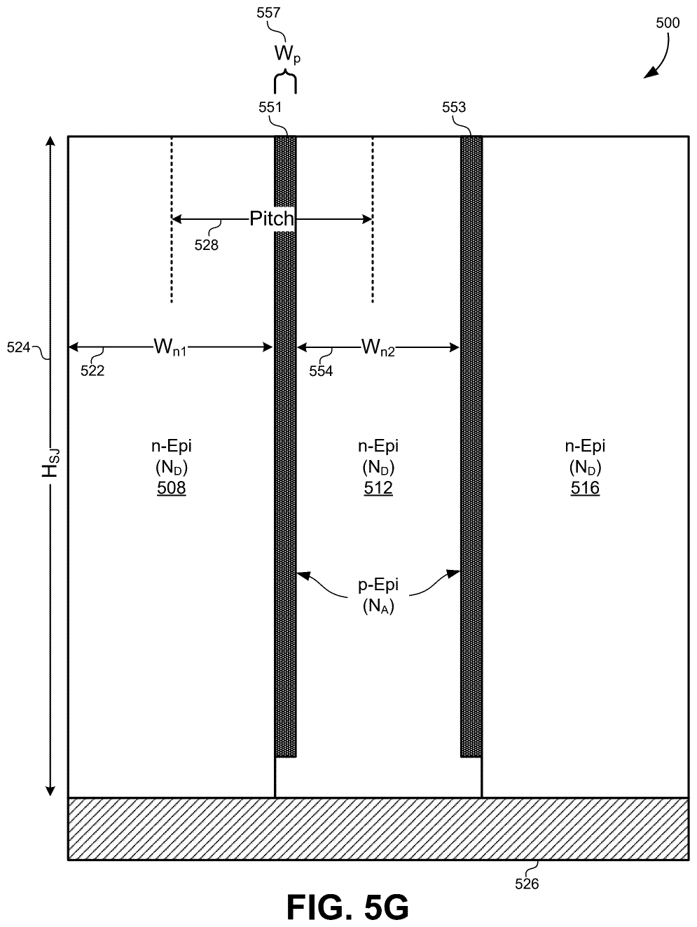

FIGS. 5A-5G illustrate incremental structures for forming the asymmetric super junction device with diffusion barriers, according to some embodiments. The method of flowchart 400 describes operations shown structurally in FIGS. 5A-5G, the illustrations of which will be described in conjunction with the operations of this method. It is to be understood that the figures illustrate only partial structural views with limited details, and in some embodiments a substrate may contain any number of semiconductor sections or layers having features as illustrated in the figures, as well as alternative structural features that may still benefit from any of the aspects of the present technology.

The method of flowchart 400 may include forming a first N-type region over a substrate (402). As illustrated in FIG. 5A, the structure 500 may include a substrate 526. The substrate 526 may have a substantially planar surface or an uneven surface in various embodiments. The substrate 526 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. As one non-limiting example, the substrate may be or include an N+ material, such as N+ silicon. The substrate 526 may have various dimensions, such as 200 mm or 300 mm diameter wafers, as well as rectangular or square panels. The substrate 526 may be disposed within the processing region of the semiconductor processing chamber. Although shown as a planar substrate, it is to be understood that substrate 526 is included merely to represent an underlying structure, which may include any number of layers or features on a wafer or other substrate, and over which structures as described below may be formed.

Above the substrate 526, the structure 500 may include a first N-type material. The first N-type material may be disposed along at least a portion or all of the substrate 526. The first N-type silicon-containing material may be N-type silicon, and which may be doped with phosphorous, arsenic, a combination of both, or other similar materials. Throughout this disclosure, any of the substrate, the N-type materials, and/or the P-type materials may be formed using any type of semiconductor material, including silicon, silicon carbide, silicon germanium, GaN, AlGaN, and other similar materials.

The first N-type material may form the first N-type region 508, although the mesa or pillar of the first N-type region 508 (and possibly other N-type regions 516) may not become apparent until after a trench is etched in the following operation. The height 524 of the first N-type material and the subsequent first N-type region 508 may be greater than or about 10 μm, between about 10 μm and about 20 μm, between about 20 μm and about 30 μm, between about 30 μm and about 40 μm, between about 40 μm and about 50 μm, between about 50 μm and about 60 μm, between about 60 μm and about 70 μm, between about 70 μm and about 80 μm, greater than or about 80 μm, and so forth. The height 524 may also include any combination of intervals described above (e.g., between about 40 μm and about 80 μm, etc.). The height 524 may also include any individual value within the regions described above (e.g., about 70 μm, greater than or about 70 μm, etc.). For example, a device having a 1300 V breakdown voltage may have a first N-type region 508 that is about 80 μm high. For devices having a breakdown voltage greater than 650 V, the height of the first N-type region 508 may be greater than or about 50 μm, greater than or about 60 μm, greater than or about 70 μm, and/or greater than or about 80 μm. Other embodiments may include a first N-type region 508 that is less than about 40 μm, which may be used to form super junction devices with a smaller overall width. Other embodiments may also include a first N-type region that is greater than or about 90 μm, greater than or about 100 μm, and so forth, depending on the desired voltage characteristics of the super junction device.

In some embodiments, to facilitate patterning of the first N-type material, hard masks, photoresists, or any other mask materials may be disposed along the first N-type material. For example a first mask may be formed over the first N-type material, and a second mask may be formed over the first mask. In some embodiments, either or both masks may be any number of materials to promote structural formation, such as oxides, nitrides, carbides, or some combination of materials. For example, the first mask may be or include silicon nitride, and the second mask may be or include silicon oxide, or some other mask material. It is contemplated that a singular mask may be provided over the first N-type material and the embodiment depicted in FIG. 5A is merely one example structure 500.

The method of flowchart 400 may also include etching a trench 533 in the first N-type material (404). As shown in FIG. 5A, a pattern may be etched or formed through the first mask and/or the second mask to form features, such as the trench 533. The trench 533 may be etched through the first mask and/or the second mask using any etching processes and any etching reagents. In some embodiments, the etching may completely remove the second mask as a pattern is transferred into the underlying N-type material.

The etching of the first N-type material may form one or more trenches in the material. The trench 533 may be formed to a depth of greater than or about 10 μm, and may be formed to a depth of greater than or about 15 μm, greater than or about 20 μm, greater than or about 25 μm, greater than or about 30 μm, greater than or about 35 μm, greater than or about 40 μm, greater than or about 45 μm, greater than or about 50 μm, greater than or about 55 μm, greater than or about 60 μm, greater than or about 65 μm, greater than or about 70 μm, greater than or about 75 μm, greater than or about 80 μm, greater than or about 85 μm, greater than or about 90 μm, greater than or about 95 μm, greater than or about 100 μm, or greater. As illustrated in FIG. 5A, the trench 533 may extend into the first N-type material, but stop short of a top surface of the substrate 526. Alternatively, the trench 533 may extend all the way down to a top surface of the substrate 526. In some embodiments, the trench 533 may extend below a top surface of the substrate 526 such that the trench 533 penetrates the substrate 526. As described below, this provides a surface from which epitaxial silicon may be grown from the substrate 526 when filling the trench 533. Therefore, the depth of the trench 533 correspond to any of the depths described above for the first N-type region 508 or deeper.

Note that decreasing the depth of the trench 533 may also be reduced to reduce the breakdown voltage proportionally, since the breakdown voltage is directly related to the height of the device. For example, the depth may be reduced heights below 80 μm corresponding to a breakdown voltage of greater than or about 1200 V, greater than or about 1100 V, greater than or about 1000 V, greater than or about 900 V, greater than or about 800 V, greater than or about 700 V, or greater than or about 650 V.

The trench 533 may have an aspect ratio, or a depth-to-width ratio less than or about 50, less than or about 40, less than or about 30, less than or about 25, less than or about 20, less than or about 15, less than or about 10, or less. Additionally the trench 533 may be formed to a width of greater than or about 1.5 μm, greater than or about 2.0 μm, greater than or about 2.5 μm, greater than or about 3.0 μm, greater than or about 3.5 μm, greater than or about 4.0 μm, greater than or about 4.5 μm, greater than or about 5.0 μm, greater than or about 6.0 μm, greater than or about 7.0 μm, greater than or about 8.0 μm, greater than or about 9.0 μm, greater than or about 10.0 μm, or greater. The trench 533 may also be formed to a width of between about 1.5 μm in about 2.0 μm, between about 2.0 μm and about 2.5 μm, between about 2.5 μm in about 3.0 μm, between about 3.0 μm and about 3.5 μm, between about 3.5 μm and about 4.0 μm, between about 4.0 μm and about 4.5 μm, between about 4.5 μm, and about 5.0 μm, between about 4.5 μm and about 6.0 μm, and so forth.

While conventional methods may strive for etching higher aspect ratio trenches to allow for narrower and deeper P-type regions to be deposited, forming trenches with higher aspect ratios may make structural formation more difficult. Not only may it be difficult to etch high aspect ratio trenches with consistent diameters, but it may also be difficult to backfill these trenches uniformly with the P-type material. Instead, the P-type material may have seams and/or voids present due to pinch off at the top of the feature during fill. Conversely, the embodiments described herein may counterintuitively allow for relaxing the width of the trench 533 to produce smaller pitch structures or higher aspect ratio structures, which may allow for more uniform etching and subsequent backfill. Further, with an increased width of the trench 533, deeper etching of the N-type material may be afforded. As an additional benefit of deeper etching, and therefore deeper structures of material, increased breakdown voltages for power devices produced by the present technology may be afforded compared to conventional methods and technology. For example, the 650 V device 200 illustrated in FIG. 2 may have trenches etched at approximately 2 μm wide, 40 μm deep, with an aspect ratio of 20. By relaxing the width of the trench 533, a 1300 V device of FIG. 3 may have trenches etched at approximately 4 μm wide, 80 μm deep, still with an aspect ratio of 20. As described below, the pitch of the N-type and P-type pillars may be maintained at approximately 4 μm, such that the overall width of the 1300 V device is about the same as the width of the 650 V device.

The method of flowchart 400 may include forming a diffusion barrier on a sidewall portion of the first N-type material in the trench (406). The method may further include forming a P-type liner 550 on a sidewall portion of the first N-type region 508 in the trench 533 (408). FIG. 5B illustrates forming a P-type liner 550 on a sidewall portion of the first N-type region 508 in the trench 533, according to some embodiments. FIG. 5C illustrates how the P-type liner 550 may include one or more diffusion barriers surrounding an internal P-type layer, according to some embodiments. For example, the P-type liner 550 may include a trilayer stack of two thin diffusion barriers 571, 573 on either side of a P-type epitaxial layer 572. Each of these layers of the trilayer stack may be formed through epitaxial growth, one on top of the other. Therefore, some embodiments of the trilayer stack may include the first diffusion barrier 571, the P-type epitaxial layer 572, and the second diffusion barrier 573 formed without an air break in between. Some embodiments may also form these layers directly one on top of the other, making direct contact with each other without any intervening layers. Alternatively, some embodiments may allow for thin intervening layers between the diffusion barriers 571, 573, the P-type epitaxial layer 572, and/or the surrounding N-type regions.

The diffusion barriers may be configured to completely block or greatly reduce diffusion of a P-type dopant of the P-type epitaxial layer 572 into the surrounding N-type regions. For example, the diffusion barriers may be configured to prevent boron from a boron-doped P-type epitaxial layer 572 from migrating into the surrounding N-type region(s). This diffusion of the P-type dopants may occur during the high temperatures experienced during subsequent steps of the manufacturing process. For example, the diffusion barriers may be specifically configured to prevent P-type dopant diffusion at temperatures above about 300° C., above about 400° C., above about 500° C., above about 600° C., above about 700° C., and so forth. Although not shown in FIG. 5C, the diffusion barriers may also prevent P-type dopant diffusion into a silicon fill material used to fill the trench 533 in subsequent operations as described below.

The P-type liner 550 comprising the trilayer stack may have a target thickness of between about 10 nm and about 20 nm, between about 20 nm and about 50 nm, between about 50 nm and about 100 nm, between about 100 nm and about 150 nm, between about 150 nm and about 200 nm, between about 200 nm and about 250 nm, between about 250 nm and about 300 nm, or greater than about 300 nm. The P-type liner 550 may have a thickness that includes any combination of the ranges described above (e.g., between about 50 nm and about 200 nm, greater than about 150 nm, etc.). The P-type liner 550 may also be thickness that includes any individual value in the combination of ranges above (e.g., a target thickness of about 200 nm).

The thickness of the diffusion barriers 571, 573 may be relatively thin in comparison to a thickness of the P-type epitaxial layer 572. For example, the thickness of each of the diffusion barriers 571, 573 may be less than or about 25% of the total thickness of the P-type liner 550 comprising the trilayer stack. In other embodiments, the thickness of the diffusion barriers 571, 573 may be less than or about 20%, less than or about 15%, less than or about 10%, less than about 8%, or less than about 5% of the total thickness of the P-type liner 550 comprising the trilayer stack. Accordingly, the thickness of the diffusion barriers 571, 573 may be between about 1 nm and about 2 nm, between about 2 nm and about 4 nm, between about 4 nm and about 6 nm, between about 6 nm and about 8 nm, between about 8 nm and about 10 nm, between about 10 nm and about 12 nm, between about 12 nm and about 14 nm, between about 14 nm about 16 nm, between about 16 nm and about 18 nm, between about 18 nm and about 20 nm, and/or greater than about 20 nm. The thickness of the diffusion barriers 571, 573 may have a thickness that includes any combination of the ranges described above (e.g., between about 1 nm and about 10 nm, greater than about 14 nm, etc.). The thickness of the diffusion barriers 571, 573 may also be a thickness that includes any individual value in the combination of ranges above (e.g., a target thickness of about 10 nm).

The diffusion barriers may be formed from any type of material configured to prevent diffusion of P-type dopants from the P-type epitaxial layer 572 into a surrounding silicon layer, such as the N-type region 516. For example, some embodiments may form the diffusion barriers from silicon germanium (SiGe) with a germanium content of between about 5% and about 50%. Some embodiments may perform the diffusion barriers from carbon-doped silicon (Si:C) with a carbon content between about 1% and about 10%. Some embodiments may form the diffusion barriers from oxygen-doped silicon (SI:O) or oxygen-doped silicon germanium (SiGeₓO_{y}). Some embodiments may form the diffusion barriers from carbon-doped silicon germanium (SiGcₓC_{y}). The first diffusion barrier 571 may be formed from the same material as the second diffusion barrier 573 and may have a similar thickness. Alternatively, the first diffusion barrier 571 and the second diffusion barrier 573 may be formed from different materials and may have different thicknesses.

The first diffusion barrier 571 may be first formed on the interior of the trench 533. For example, the first diffusion barrier 571 may be formed through epitaxial growth in an epitaxy chamber. The first diffusion barrier 571 may be formed on sidewalls of the N-type material inside of the trench. For example, the first diffusion barrier 571 may be formed on the vertical sidewalls on the first N-type region 508 and the N-type region 516 in FIG. 5A. Some embodiments may also form the first diffusion barrier 571 along a bottom of the trench 533. This may be formed on the N-type silicon at the bottom of the trench, or on/in the substrate 526, depending on how deep the trench 533 is etched as described above. The first diffusion barrier 571 may also be formed on top of the mesas or pillars that form the first N-type region 508 and/or the N-type region 516 as illustrated in FIG. 5B.

Next, the P-type epitaxial layer 572 may be formed on the first diffusion barrier 571. The deposition or formation may be performed in any number of ways, and in some embodiments the material may be formed conformally about the exposed surfaces in the trench 533. The P-type epitaxial layer 572, which may be p-type silicon, for example, may be deposited by atomic layer deposition, grown epitaxially, or produced by any number of other processes to produce conformal coverage about the trench 533. By having trenches characterized by wider width, the coverage may be uniform despite the greater depth of the trench 533. The P-type epitaxial layer 572 may be characterized by a thickness of between about 50 nm and about 100 nm, between about 100 nm and about 150 nm, between about 150 nm and about 200 nm, between about 200 nm and about 250 nm, between about 250 nm and about 300 nm, greater than or about 300 nm, and so forth. The P-type epitaxial layer 572 may also be characterized by a thickness of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, or less. The P-type epitaxial layer 572 may be a silicon-containing material doped with boron or other similar materials. In some embodiments, the P-type liner 550 may also include germanium.

The P-type epitaxial layer 572 may substantially cover the sidewall portion of the first N-type region 508 in the trench 533 and on top of the first diffusion barrier 571. In some embodiments, the P-type epitaxial layer 572 may also be formed on the bottom of the trench 533 over the first diffusion barrier 571 and along the top surface of the pillars or maces formed by the N-type material. The P-type epitaxial layer 572 may be free of seams and/or voids based on the conformal coverage about the structure, even to a depth of several hundred nanometers, which may provide large improvements on performance for final devices compared to conventional technologies that have reduced or incomplete coverage at greater depths, as well as seam or void formation. However, it is contemplated that some pores may be present in the P-type epitaxial layer 572, depending on the formation and thickness.

The second diffusion barrier 573 may be formed at this stage or later in the process as described below. For example, the second diffusion barrier 573 may be formed over the P-type epitaxial layer 572. The second diffusion barrier 573 may be formed using the thicknesses, processes, materials, and/or other characteristics described above for forming the first diffusion barrier 571 in any combination and without limitation. Alternatively, the second diffusion barrier 573 may be formed after performing the directional etch described below.

FIG. 5D illustrates the formation of a passivation layer 555 as part of an optional operation that may be added to the method of flowchart 400 in some embodiments. The passivation layer 555 may be formed by providing an oxygen-containing precursor to the processing region. The oxygen-containing precursor may be any number of precursors that may oxidize or form on the P-type liner 550. As non-limiting examples, the oxygen-containing precursor may be or include diatomic oxygen, ozone, nitrous oxide, nitric oxide, sulfur dioxide or any other oxygen-containing precursors which may be delivered with or without plasma enhancement, and may be used to oxidize a depth of the existing material, or may be delivered with any other precursor, such as a silicon-containing precursor to deposit an oxide layer. The passivation layer 555 may be formed by using any deposition or growth method. The oxygen-containing material in the passivation layer 555 may oxidize and passivate at least a portion of the P-type liner 550. The passivation layer 555 may serve to protect the P-type liner 550 during subsequent etch operations.

FIG. 5E illustrates the result of a directional etch to remove the P-type liner 550 and/or the passivation layer 555 from the bottom of the trench 533. The portion of the P-type liner 550 that is removed may be located at a bottom of the trench 533. In addition to the portion of the P-type liner 550 that is removed, a portion of the passivation layer 555 may also be removed. The portion of the passivation layer 555 that is removed may be located at a bottom of the trench 533. In some embodiments, removing the portion of the P-type liner 550 may include an anisotropic etching process, such as a reactive-ion etching operation or any other directional dry etch process. For example, the method of flowchart 400 may include applying bias power to etch the bottom of the passivation layer 555 and/or the P-type liner 550. The etching of the passivation layer 555 may be due to a sputtering of the oxide in the passivation layer 555, while a more chemical-based removal may occur through the p-type silicon of the P-type liner 550, or vice versa. The bottom of the passivation layer 555 may be sputtered and removed at a faster rate than the sidewalls of the passivation layer 552 due to the anisotropicity of the etch. Therefore, this operation may remove the P-type liner 550 and the passivation layer 555 from the bottom of the trench 533 while leaving the P-type liner 550 and at least a portion of the passivation layer 555 along the sidewall portion of the trench 533. As illustrated in FIG. 5E, this directional etch may expose the N-type material at the bottom of the trench 533. In embodiments where the trench is down to or below a top surface of the substrate 526, this directional etch may expose the surface or interior of the substrate 526 at the bottom of the trench 533.

FIG. 5F illustrates the removal of the remaining portion of the passivation layer 555, according to some embodiments. The method of flowchart 400 may optionally include removing the remaining portion of the passivation layer 555. The portion of the passivation layer 555 that is removed may be located along sidewalls of the trench 553 and overlying P-type liner 550. In some embodiments, removing the portion of the passivation layer 555 may include, as one non-limiting example, a wet etching operation using any wet etching reagent(s), such as halogen-containing materials. However, it is contemplated that other forms of etching may alternatively or additionally be utilized including dry etch processes.

The remaining P-type liner 550 may now be present on the sidewalls of the trench 553. The P-type liner 550 may be characterized by an aspect ratio of greater than or about 50, greater than or about 100, greater than or about 150, greater than or about 200, greater than or about 250, greater than or about 300, greater than or about 350, greater than or about 400, or more. With taller, narrower features than conventional methods, super junction devices formed using these structures may be characterized by reduced on-resistance due to the separation distances between N-type regions, and may be characterized by increased breakdown voltages due to the depth and uniformity of the P-type pillars formed.

Optionally, the second diffusion barrier 573 may now be formed on the P-type epitaxial layer 572 if the second diffusion barrier 573 has not already been formed. For example, the P-type liner 550 may only include the first diffusion barrier 571 and the P-type epitaxial layer 572 if the second diffusion barrier 573 was not formed prior to the passivation layer 555. After removing the passivation layer 555, the second diffusion barrier 573 may be formed on the sidewalls of the trench 533 over and in direct contact with the P-type epitaxial layer 572 as illustrated in FIG. 5C. Other embodiments may allow other intervening layers between the P-type epitaxial layer 572 and the second diffusion barrier 573. Note that this may also form a portion of the second diffusion barrier 573 along a bottom of the trench 533. However, the second diffusion barrier 573 may be thin enough that this small layer will not significantly affect the resistance of the super junction device.

The method of flowchart 400 may include filling the trench 533 with a silicon material (410). For example, the trench 533 may be filled with an N-type silicon material to form a second N-type region 512 such that the P-type liner 550 is between the first N-type region 508 and the second N-type region 512 (406). FIG. 5G illustrates the formation of the second N-type region 512, according to some embodiments. The second N-type region 512 may fill the trench 533 by backfilling the internal region of the trench 533 between the sidewalls on which the P-type liner 550 has been formed. The second N-type region 512 may fill the trench 533 free of any voids and without intermittent etching based on the increased width that may be afforded from the initial trench formation (e.g., about 4 μm). The second N-type region 512 may be the same material as the first N-type region 508 or may be doped with a different material. Together, the N-type region 508 and the second N-type region 512 may at least partially surround the P-type liner 550. The P-type liner 550 may now be referred to as a P-type region 551 in the super junction device. The trench 533 may be filled with N-type material through an epitaxial growth process. For example, the exposed substrate 526 or exposed N-type material at the bottom of the trench may provide a base for epitaxially growing N-type silicon material up from the substrate 526 to fill the trench 533.

In some embodiments, the silicon material used to fill the trench 533 need not be doped N-type silicon. For example, some embodiments may use undoped silicon that is epitaxially grown to fill the trench 533. Alternatively, silicon oxide may be formed inside of the trench 533 using a chemical vapor deposition (CVD) process. Other silicon-based materials may also be used. For example, the second N-type region 512 in FIG. 5G may be replaced with other silicon materials, including undoped silicon and silicon oxide.

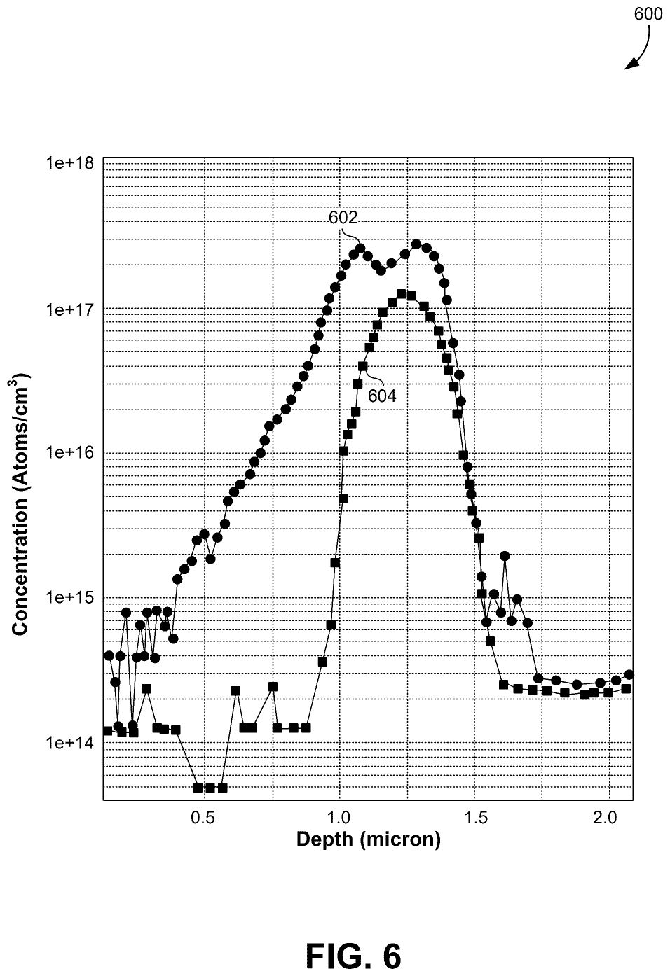

FIG. 6 illustrates a graph 600 of the concentration of dopants in the P-type liner, according to some embodiments. Specifically, the boron profile of the concentration of boron atoms in the super junction device is illustrated in the graph 600 for devices with and without diffusion barriers. Curve 602 illustrates the boron concentration without a diffusion barrier. As illustrated, the drop-off from the boron concentration in the P-type region (between about 1e+17 and about 1e+18 atoms/cm³) is very gradual and extends into the neighboring N-type region (less than 1.0 μm in-depth on the graph 600). In contrast, curve 604 illustrates the boron concentration with the diffusion barriers described above. As illustrated, the drop-off from the boron concentration in the P-type region is more immediate and represents the desired abrupt interface between the N-type regions and the P-type regions.

A ratio of a width of the second N-type region 512 to a width of the P-type region 551 may be greater than or about 15, and may be greater than or about 20, greater than or about 22, greater than or about 24, greater than or about 26, greater than or about 28, greater than or about 30, or more. The ratio between the two materials may lead to a reduction of on-resistance in subsequent devices produced with these structures, as previously discussed. Alternatively stated, a width 557 of the P-type region 551 may be less than or about 10% of a combined width of the P-type region 551 and the second N-type region 512. The width 557 of the P-type region 551 may also be less than or about 9%, less than or about 8%, less than or about 7%, less than or about 6%, less than or about 5%, and so forth, of this combined width. For example, a P-type region 551 with a width 557 of 200 nm may be formed with a second N-type region 512 with a width 554 that is 3.8 μm in a trench that is 4.0 μm wide and 80 μm high.

Additional operations may include removing a portion of the N-type material and any remaining mask material by planarizing the structure, such as with a chemical-mechanical polishing operation. The method may also optionally include forming the remaining contact regions for the structure 500. For example, the structure 500 of FIG. 5G may be further processed to include the source terminal, gate terminal, and other features as illustrated in the device 300 of FIG. 3.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a pillar” includes a plurality of such pillars, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMS, EEPROMs, magnetic or optical cards, flash memory, or other types of machine-readable mediums suitable for storing electronic instructions. Alternatively, the methods may be performed by a combination of hardware and software.

What is claimed is:

1. An super junction device comprising:
an N-type region extending between a gate and a substrate of the super junction device;
a P-type region extending between a source contact region and the substrate of the super junction device; and
a diffusion barrier between the P-type region and the N-type region.

2. The super junction device of claim 1, wherein a width of the P-type region comprises less than or about 10% of a combined width of the P-type region and the N-type region.

3. The super junction device of claim 1, further comprising a second diffusion barrier between the P-type region and a second N-type region, wherein the P-type region is between the N-type region and the second N-type region.

4. The super junction device of claim 1, wherein the diffusion barrier reduces diffusion of P-type dopants in the P-type region into the N-type region.

5. The super junction device of claim 1, wherein a doping concentration of the N-type region is between about 1e14 dopants/cm³ and about 1e16 dopants/cm³.

6. The super junction device of claim 1, wherein a doping concentration of the P-type region is greater than about 8 times a doping concentration of the N-type region.

7. The super junction device of claim 1, wherein a height of the P-type region is greater than or about 70 μm and a width of the P-type region is less than or about 200 nm.

8. A super junction device comprising:
a first N-type pillar;
a second N-type pillar;
a P-type liner between the first N-type pillar and the second N-type pillar; and
diffusion barriers between the P-type liner and the first N-type pillar and between the P-type liner and the second N-type pillar.

9. The super junction device of claim 8, wherein a height of the first N-type pillar is greater than about 80 μm, and the super junction device has a breakdown voltage of greater than or about 1200 V.

10. The super junction device of claim 8, wherein a doping concentration of the P-type liner is higher than a doping concentration of the first N-type pillar.

11. The super junction device of claim 8, wherein the diffusion barriers comprise doped silicon.

12. The super junction device of claim 8, wherein the diffusion barriers comprise doped silicon germanium.

13. The super junction device of claim 8, wherein the diffusion barriers are between about 1 nm and 10 nm thick.

14. A method of forming a super junction device, the method comprising:
forming an first N-type material over a substrate;
etching a trench in the first N-type material;
forming a diffusion barrier on a sidewall portion of the first N-type material in the trench;
forming a P-type liner on the diffusion barrier; and
filling the trench with a semiconductor material.

15. The method of claim 14, further comprising forming a second diffusion barrier on the P-type liner.

16. The method of claim 14, further comprising forming an oxide layer over the P-type liner and on a bottom of the trench.

17. The method of claim 16, further comprising performing a directional etch to remove the P-type liner from the bottom of the trench while leaving the P-type liner along the sidewall portion of the trench.

18. The method of claim 14, wherein the P-type liner is less than or about 300 nm thick.

19. The method of claim 14, wherein a doping concentration of the N-type material is between about 1e14 dopants/cm³ and about 1e16 dopants/cm³.

20. The method of claim 19, wherein the diffusion barrier and the P-type liner are epitaxially formed.
